(19) United States
(12) Patent Application Publication
(10) Pub. No.: US 2016/0288373 A1
(43) Pub. Date: Oct. 6, 2016

(54) IMPRINT LITHOGRAPHY METHOD, METHOD FOR MANUFACTURING MASTER TEMPLATE USING THE METHOD, AND MASTER TEMPLATE MANUFACTURED BY THE METHOD

(71) Applicant: Samsung Display Co., Ltd., Yongin-si (KR)

(72) Inventors: Tae-Woo Kim, Seoul (KR); Jung-Gun Nam, Suwon-si (KR); Min-Hyuck Kang, Seoul (KR); Dae-Young Lee, Seoul (KR); Gug-Rae Jo, Asan-si (KR)

(21) Appl. No.: 14/881,909

(22) Filed: Oct. 13, 2015

(30) Foreign Application Priority Data
Apr. 6, 2015 (KR) 10-2015-0048220

(51) Int. Cl. B29C 33/38; G03F 7/00

(52) U.S. Cl. CPC B29C 33/3842; G03F 7/0002; B29K 2995/0027

(57) ABSTRACT

An imprint lithography method includes providing a substrate, forming a first imprint pattern, forming a first resist pattern, etching an object, removing the first resist pattern, forming a second imprint pattern, forming a second resist pattern, etching the object and removing the second resist pattern. The substrate includes a first area, a second area, a third area, and a fourth area. The first imprint pattern is formed on the base substrate in the first and third area. The first resist pattern is formed configured to cover the second area on the base substrate on which the first imprint pattern is formed. The second imprint pattern is formed on the base substrate in the second and fourth areas. The second resist pattern is formed configured to cover the first area on the base substrate on which the second imprint pattern.

### CROSS REFERENCE TO RELATED APPLICATION

This application claims priority from and the benefit of Korean Patent Application No. 10-2015-0048220, filed on Apr. 6, 2015, which is hereby incorporated by reference for all purposes as if fully set forth herein.

### BACKGROUND

1. Field

Exemplary embodiments relate to an imprint lithography method, a manufacturing method for a master template using the imprint lithography method, and a master template manufactured by the manufacturing method. More particularly, exemplary embodiments relate to a large-area imprint lithography method, a manufacturing method for a master template using the imprint lithography method, and a master template manufactured by the manufacturing method.

2. Discussion of the Background

Recently, a display apparatus having light weight and small size has been manufactured. Previously, a cathode ray tube (CRT) display apparatus was commonly used due performance advantages and a competitive pricing. However, the CRT display apparatus has a large size and weight and, therefore, lacks portability. Thus, a display apparatus such as a plasma display apparatus, a liquid crystal display apparatus, and an organic light emitting display apparatus, are currently highly regarded due to their small size, light weight, and relatively low power-consumption.

A liquid crystal display apparatus applies a voltage to a specific molecular arrangement in order to change the molecular arrangement. The liquid crystal display apparatus displays an image using changes of optical property (for example, birefringence, rotatory polarization, dichroism, and light scattering) of a liquid crystal cell according to the changes in the molecular arrangement.

The liquid crystal display apparatus typically includes a polarizer for controlling the molecular arrangement of the liquid crystal, a display panel, an optical sheet, and a backlight assembly. Recently, in-cell polarizers have been developed for use as the polarizer. For example, a wire grid polarizer is a type of in-cell polarizer used in liquid crystal display apparatuses. The wire grid polarizer may be formed by imprint lithography process. However, because of size limitations for master template for, the manufacture of a large display panels utilizing such a process has proven to be difficult.

The above information disclosed in this Background section is only for enhancement of understanding of the background of the inventive concept, and, therefore, it may contain information that does not form the prior art that is already known in this country to a person of ordinary skill in the art.

### SUMMARY

Exemplary embodiments provide a large-area imprint lithography method.

Exemplary embodiments also provide a manufacturing method for a master template using the imprint lithography method.

Exemplary embodiments also provide a master template manufactured by the manufacturing method.

Additional aspects will be set forth in the detailed description which follows, and, in part, will be apparent from the disclosure, or may be learned by practice of the inventive concept.

According to an exemplary embodiment, an imprint lithography method includes providing a substrate, forming a first imprint pattern, forming a first resist pattern, etching an object, removing the first resist pattern, forming a second imprint pattern, forming a second resist pattern, etching the object and removing the second resist pattern. The substrate includes a first area, a second area adjacent to the first area, a third area which is a portion of the second area and contacts to a boundary of the first area and the second area, and a fourth area which is a portion of the first area and contacts to the boundary. The first imprint pattern is formed on the base substrate in the first and third area. The first resist pattern is formed configured to cover the second area on the base substrate on which the first imprint pattern is formed. The object under the first imprint pattern is etched using the first imprint pattern and the first resist pattern as an etch barrier. The second imprint pattern is formed on the base substrate in the second and fourth areas. The second resist pattern is formed configured to cover the first area on the base substrate on which the second imprint pattern. The object under the second imprint pattern is etched using the second imprint pattern and the second resist pattern as an etch barrier.

According to an exemplary embodiment, a method of manufacturing a mater template for imprint lithography includes forming a first layer and mask layer on a bases substrate, orderly, forming a first imprint pattern on a first portion of the mask layer, forming a first mask pattern by etching the first area of the mask layer using the first imprint pattern as an etch barrier, forming a second imprint pattern on a second portion of the mask layer which is adjacent to the first mask pattern, forming a photoresist layer on the base substrate on which the second imprint pattern is formed, forming a resist pattern on the first mask pattern by back exposure and development of the photoresist layer, forming a second mask pattern by etching the second portion of the mask layer using the second imprint pattern and the resist pattern as an etch barrier, and etching the first layer using the first and second mask pattern as an etch barrier.

According to an exemplary embodiment, a master template for imprint lithography includes a base substrate including a first area and a second area contacting to the first area, and a master pattern disposed in the first area and the second area on the base substrate. The master pattern include protrusions in the first and second area, the protrusions are spaced apart from each other by a predetermined distance and have same shapes. Sum of width of the protrusion and distance between adjacent protrusions is defined as pitch. A pitch of the protrusion at the nearest to a boundary of the first area and the second area has about ½ to 3/2 of the pitch.

The foregoing general description and the following detailed description are exemplary and explanatory and are intended to provide further explanation of the claimed subject matter.

### BRIEF DESCRIPTION OF THE DRAWINGS

The accompanying drawings, which are included to provide a further understanding of the inventive concept, and are incorporated in and constitute a part of this specification, illustrate exemplary embodiments of the inventive concept, and, together with the description, serve to explain principles of the inventive concept.

FIGS. 1A, 1B, 1C, 1D, 1E, 1F, 1G, 1H, 1I, 1J, 1K, 1L, 1M, 1N, 1O, and 1P are cross-sectional views illustrating an imprint lithography method according to an exemplary embodiment.

FIGS. 2A, 2B, 2C, 2D, 2E, 2F, 2G, 2H, 21, 2J, 2K, 2L, 2M, and 2N are cross-sectional views illustrating an imprint lithography method according to an exemplary embodiment.

FIGS. 3A, 3B, 3C, and 3D are cross-sectional views illustrating an imprint lithography method according to an exemplary embodiment.

### DETAILED DESCRIPTION OF THE ILLUSTRATED EMBODIMENTS

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments.

In the accompanying figures, the size and relative sizes of layers, films, panels, regions, etc., may be exaggerated for clarity and descriptive purposes. Also, like reference numerals denote like elements.

When an element or layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. Like numbers refer to like elements throughout. As used herein, the term “and/or” includes any and all combinations of one or more of the associated listed items.

Although the terms first, second, etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and will not be interpreted in an idealized or overly formal sense, unless expressly so defined herein.

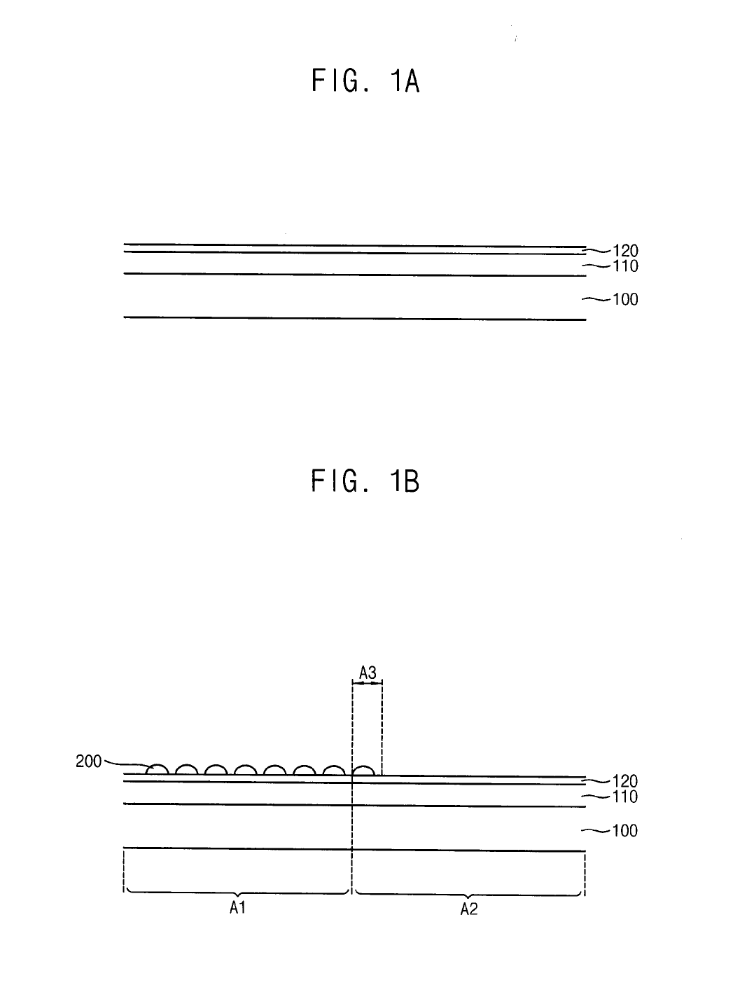

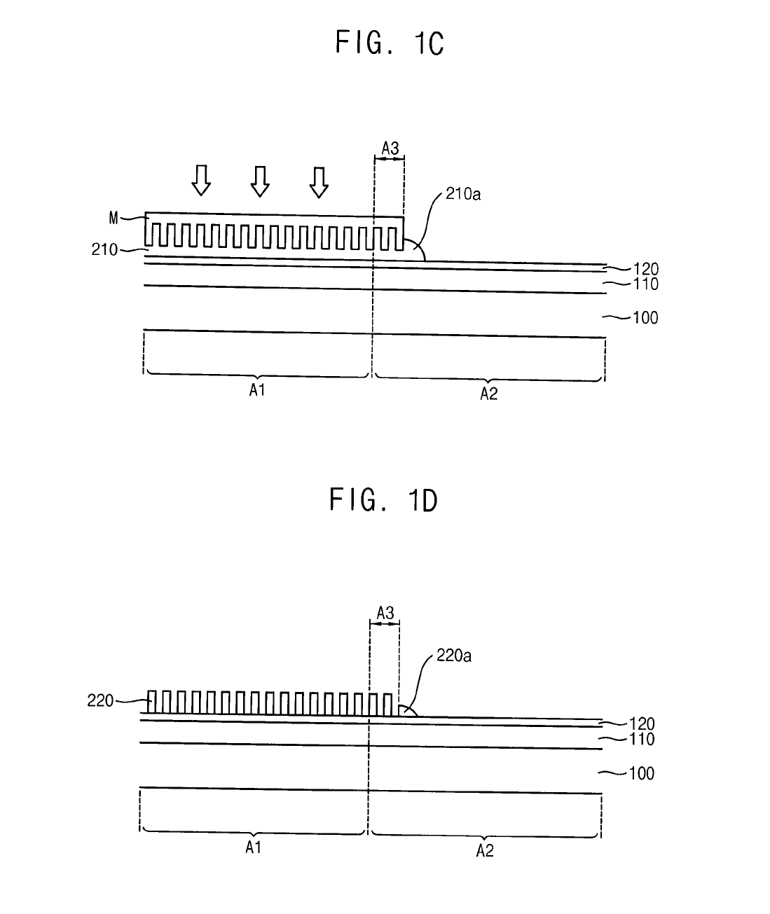

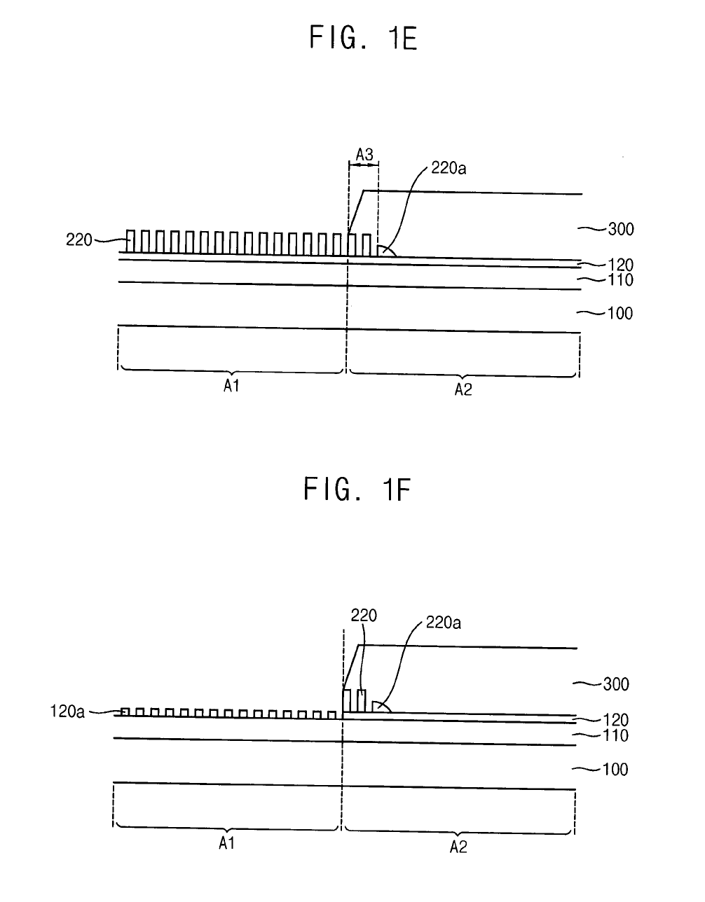

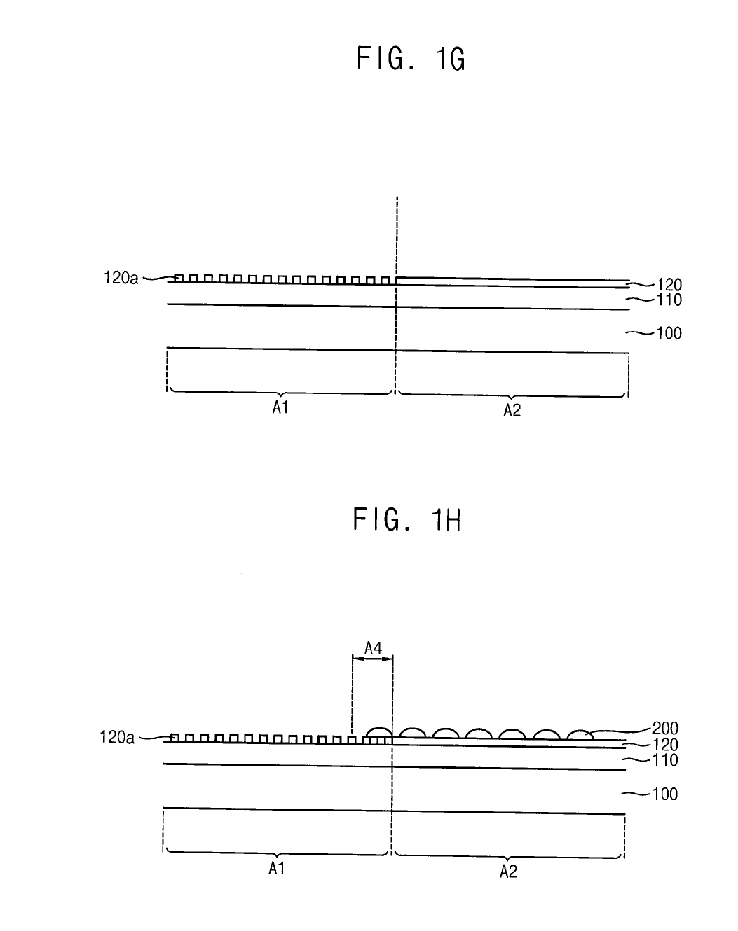

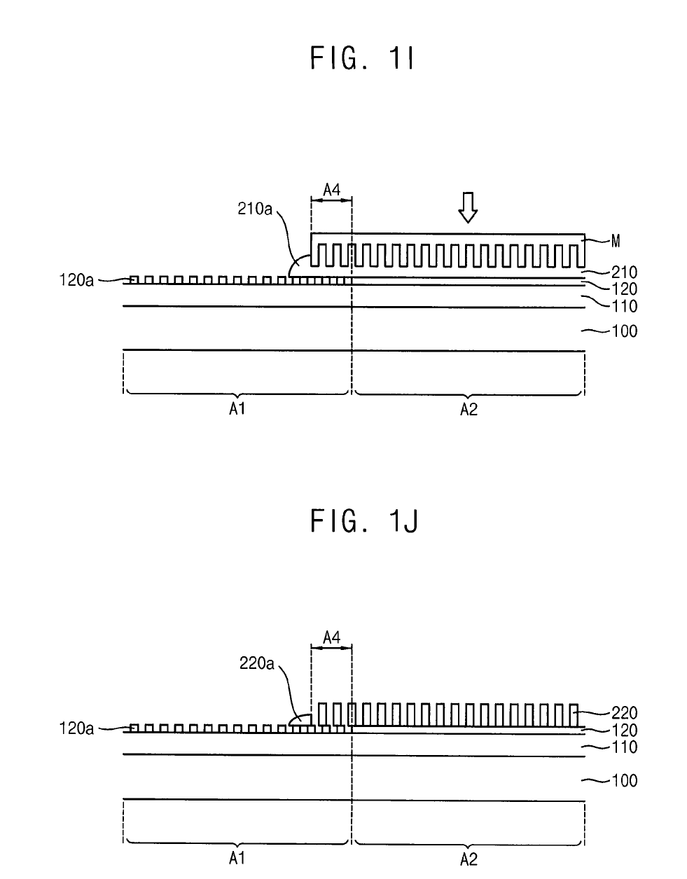

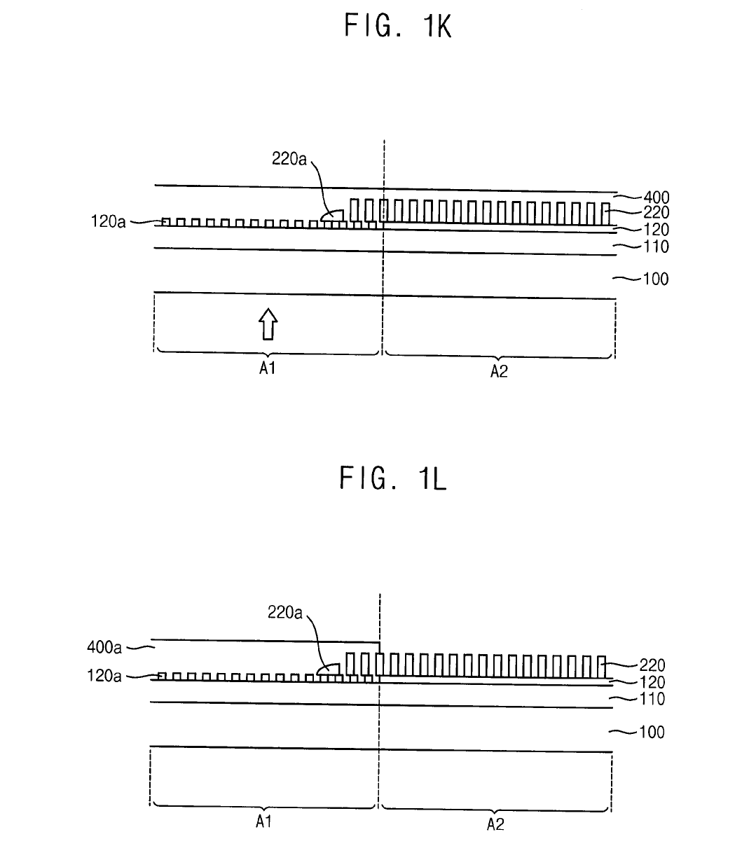

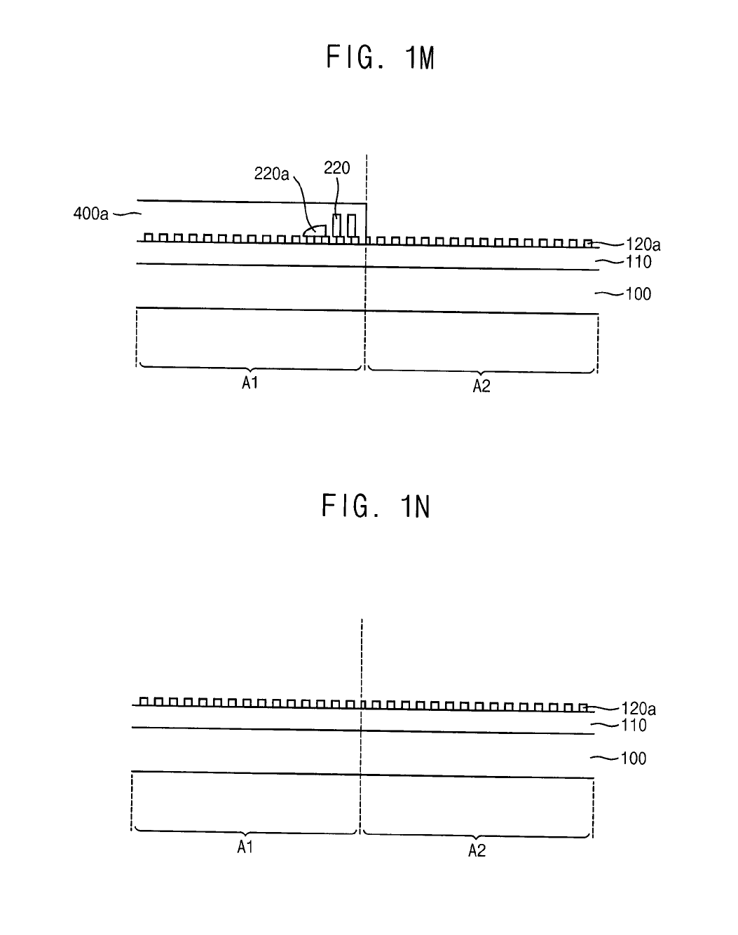

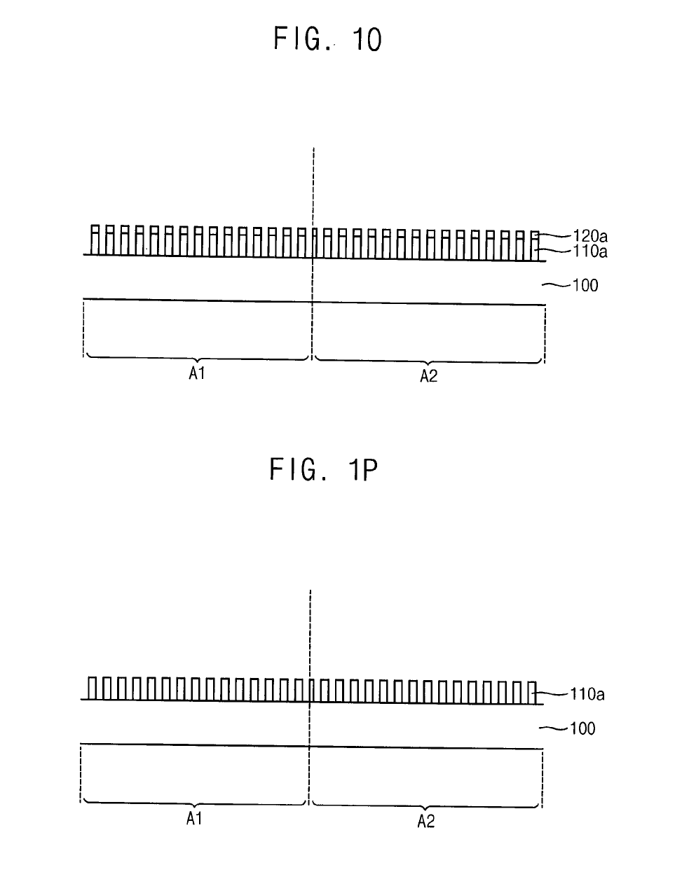

FIGS. 1A to 1P are cross-sectional views illustrating an imprint lithography method according to an exemplary embodiment.

Referring to FIG. 1A, a first may be formed on a base substrate 100. The base substrate 100 may include a material having relatively high transmittance, thermal resistance, and chemical resistance. For example, the base substrate 100 may include any one of glass, polyethylenenaphthalate, polyethylene terephthalate, polyacryl, and a mixture thereof.

The base substrate 100 may include a material that passes ultraviolet rays, such as quartz, glass, polyethylene terephthalate (PET), and/or polycarbonate (PC). The base substrate 100 may include a material which passes ultraviolet rays, such that a back exposure process using ultraviolet rays (described later with reference to FIG. 1K) may be performed.

The first layer 110 may include a transparent material that passes ultraviolet rays. For example, the first layer 110 may include transparent silicon compound. For example, the first layer 110 may include silicon oxide (SiOₓ), silicon nitride (SiNₓ), silicon oxynitride (SiOₓN_{y}), silicon oxycarbide (SiOₓC_{y}), silicon carbon nitride (SiCₓN_{y}), etc. These may be used alone or in a mixture thereof. The first layer 110 may have a single layer structure or a multi-layer structure. The first layer 110 may include a material which passes ultraviolet rays, such that a back exposure process using ultraviolet rays (described later with reference to FIG. 1K) may be performed.

The first layer 110 may be disposed using a spin coating process, a chemical vapor deposition (CVD) process, a plasma enhanced chemical vapor deposition (PECVD) process, a high density plasma-chemical vapor deposition (HDP-CVD) process, a printing process, etc.

A mask layer 120 may be formed on the first layer 110. The mask layer 120 may include a material having relatively low dry etch rate in comparison with the first layer 110. For example, the mask layer 120 may be a hard mask formed by a metal, such as aluminum.

The mask layer 120 may be formed using a printing process, a sputtering process, a CVD process, a pulsed laser deposition (PLD) process, a vacuum evaporation process, an atomic layer deposition (ALD) process, etc.

Referring to FIG. 1B, a resin solution 200 may be provided on the mask layer 120 in a first area A1 and a third area A3. The resin solution 200 may be provided as a plurality of droplets on the mask layer 120. For example, the resin solution 200 may be dropped on the mask layer 120 by an inkjet method.

The first area A1 corresponds to a portion of the first base substrate 100 where a first imprint process will be performed. The first area A1 is adjacent to a second area A2 where a second imprint process will be performed. The third area A3 is a portion of the second area A2 which is adjacent to the first area A1. Thus, the resin solution 200 may be provided on the mask layer 120 in an area larger than the first area A1, so that the resin solution 200 may cover the mask layer 120 in the first area A1 and the third area A3.

The resin solution 200 may be an ultraviolet ray curable resin composition having a low viscosity.

Referring to FIG. 1C, as an imprint mold M is moved towards the base substrate 100, the resin solution 200 may be formed into a preliminary pattern 210 using the imprint mold M. Accordingly, a first imprint process may be performed. The resin solution 200 has low viscosity, so that the preliminary pattern 210 between the imprint mold M and the base substrate may be formed by capillary action.

The imprint mold M may have a mold pattern that corresponds to the first area A1 and the third area A3. The imprint mold M may include transparent material which passes the ultraviolet rays. The mold pattern may have an inverted shape of the preliminary pattern 210. For example, the mold pattern may include a protrusion pattern, each protrusion having the same shape and formed a uniform distance from the next protrusion, to form the preliminary pattern 210. The preliminary pattern 210 may correspond to a wire grid pattern. The protrusion pattern may have a pitch of about 50 nm (nanometers) to 150 nm. The pitch may be defined as a sum of the width of one of the protrusion patterns and a distance between protrusions disposed next to each other.

The resin solution 200 may be disposed in the first area A1 and the third area A3, so that the preliminary pattern 210 may be formed in the first area A1 and the third area A3. During the first imprint process, a portion of the resin solution 200 may overflow outside of the third area A3 into the second area A2, so that an overflowed portion 210a may be formed.

The preliminary pattern 210 may include a residual layer formed on the mask layer 120, and a plurality of protrusions on the residual layer. Each of the protrusions of the preliminary pattern 210 may be formed between the protrusion patterns of the mold pattern of the imprint mold M.

The ultraviolet rays may be radiated onto the preliminary pattern 210, so that resin solution of the preliminary pattern 210 may be hardened. The imprint mold M may pass the ultraviolet rays, so that the ultraviolet rays may reach the preliminary pattern 210 through the imprint mold M. Thus, the resin solution of the preliminary pattern 210 may be hardened.

Referring to FIG. 1D, an imprint pattern 220 may be formed by removing the residual layer of the preliminary pattern 210. The imprint pattern 220 may be formed in the first area A1 and the third area A3. The imprint pattern 220 may be formed by etching the preliminary pattern 210 to remove the residual layer between the protrusions. Here, the overflowed portion 210a may be partially removed, so that a residual-overflowed portion 220a may be formed in the second area A2.

Referring to FIG. 1E, a first resist pattern 300 may be formed in the second area A2 on the mask layer 120 on which the imprint pattern 220 is formed. The first resist pattern 300 may cover the imprint pattern 220 in the third area A3 and the residual-overflowed portion 220a.

Here, the first resist pattern 300 may be formed with a relatively low level of accuracy and an area where the first resist pattern 300 is not formed may correspond to the first area A1. Thus, there is no need to perform a precise alignment for the first imprint process and a second imprint process which will be mentioned later.

A photoresist layer may be formed on the mask layer 120 on which the imprint pattern 220 is formed. The first resist pattern 300 may be formed by exposure and development of the photoresist layer using an additional mask configured to allow a portion of the photoresist layer which corresponds to the second area A2 to remain.

Referring to FIG. 1F, the mask layer 120 may be partially removed using the imprint pattern 220 as a mask. Accordingly, a mask pattern 120a may be formed in the first area A1. For example, the mask layer 120 may be dry etched using the imprint pattern 220 as an etch barrier. Here, the first resist pattern 300 covers the second area A2, so that a portion of the mask layer 120 which corresponds to the second area A2 may remain, and the mask layer 120 in the first area A1 may be patterned into the mask pattern 120a. The imprint pattern 220 remaining in the first area A1 may then be removed.

Referring to FIG. 1G, the first resist pattern 300, the imprint pattern 220 remaining the third area A3, and the residual-overflowed portion 220a may be removed.

Accordingly, the mask layer 120 in the second area A2 may be exposed.

Referring to FIG. 1H, a resin solution 200 may be disposed on the mask layer 120 in the second area A2 and a fourth area A4. The resin solution 200 may be disposed as a plurality of droplets on the mask layer 120. For example, the resin solution 200 may be dropped on the mask layer 120 by an inkjet method.

The second area A2 corresponds to a portion of the first base substrate 100 where a second imprint process will be performed. The second area A2 is adjacent to a first area A1 where the first imprint process has been performed. The fourth area A4 is a portion of the first area A1 which is adjacent to the second area A2. The resin solution 200 may be disposed on a portion of the mask pattern 120a in the fourth area A4. Thus, the resin solution 200 may be disposed in an area larger than the second area A2, so that the resin solution 200 may cover the mask layer 120 and the portion of the mask pattern 120a in the second area A2 and the fourth area A4.

The resin solution 200 may be an ultraviolet ray curable resin composition having a low viscosity.

Referring to FIG. 1I, as the imprint mold M moves towards the base substrate, the resin solution 200 may form a preliminary pattern 210 using the imprint mold M. Accordingly, the second imprint process may be performed. The resin solution 200 has low viscosity, so that the preliminary pattern 210 between the imprint mold M and the base substrate may be formed by capillary action.

The imprint mold M may have a mold pattern corresponding to the second area A2 and the fourth area A4. The imprint mold M may be substantially the same as the imprint mold M which is used in the first imprint process. Thus, an imprint lithography process may be performed at an area that is larger than a size of the imprint mold M.

The imprint mold M may have a size smaller than a traditional wafer having a diagonal length of about 300 mm. However, the sum of the first area A1 and the second area A2 may be greater than a size of the traditional wafer.

The resin solution 200 may be disposed in the second area A2 and the fourth area A4, so that the preliminary pattern 210 may be formed in the second area A2 and the fourth area A4. During the second imprint process, a portion of the resin solution 200 may overflow outside of the fourth area A4 into the first area A1, such that an overflowed portion 210a may be formed.

The preliminary pattern 210 may include a residual layer formed on the mask layer 120, and a plurality of protrusions on the residual layer. Each of the protrusions of the preliminary pattern 210 may be disposed between adjacent protrusions in protrusion patterns of the mold pattern of the imprint mold M.

Ultraviolet rays may be radiated onto the preliminary pattern 210, so that resin solution of the preliminary pattern 210 may be hardened. The imprint mold M may pass the ultraviolet rays, so that the ultraviolet rays may reach to the preliminary pattern 210 through the imprint mold M. Thus, the resin solution of the preliminary pattern 210 may be hardened.

Referring to FIG. 1J, an imprint pattern 220 may be formed by removing the residual layer of the preliminary pattern 210. The imprint pattern 220 may be formed in the second area A2 and the fourth area A4. The imprint pattern 220 may be formed by etching the preliminary pattern 210 to remove the residual layer between the protrusions. Thus, the overflowed portion 210a may be partially removed, so that a residual-overflowed portion 220a may be formed in the first area A1.

Referring to FIG. 1K, a photoresist layer 400 may be formed on the mask pattern 120a and the mask layer 120 on which the imprint pattern 220 is formed. The photoresist layer 400 may include a negative type photoresist material which may be cured by light irradiation. The photoresist layer 400 may cover the imprint pattern 220 in the second area A2, the residual-overflowed portion 220a in the first area A1 and the mask pattern 120a in the first area A1.

Then, ultraviolet rays may be radiated onto a bottom surface of the base substrate 100. Thus, the ultraviolet rays may harden the photoresist layer by passing through the base substrate 100, the first layer 110, and the mask pattern 120a in the first area A1.

The base substrate 100 and the first layer 110 are transparent, such that the ultraviolet rays may pass therethrough. The mask pattern 120a in the first area A1 may correspond to a wire grid pattern, such that the ultraviolet rays may pass therethrough. On the other hand, the mask layer 120 in the second area A2 may remain without being patterned. Thus, the ultraviolet rays cannot pass the second area A2, such that the photoresist layer 400 in the second area A2 may be not exposed and only the photoresist layer 400 in the first area A1 may be exposed. Thus, during a back exposure process, only a portion of the photoresist layer 400 which corresponds to the first area A1 may be exposed and hardened by self-alignment at the boundary of the mask pattern 120a in the first area A1 and the mask layer 120 in the second area A2.

Referring to FIG. 1L, the second resist pattern 400a in the first area A1 may be formed by development of the photoresist layer 400. The second resist pattern 400a may cover the imprint pattern 220 in the first area A1 and the residual-overflowed portion 220a.

Referring to FIG. 1M, the mask layer 120 may be partially removed using the imprint pattern 220 as a mask. Accordingly, a mask pattern 120a may be formed in the second area A2. For example, the mask layer 120 may be dry etched using the imprint pattern 220 as an etch barrier. Here, the second resist pattern 400a covers the first area A1, such that the mask pattern 120a in the first area A1 may remain, and the mask layer 120 in the second area A2 may be patterned into the mask pattern 120a. Then, the imprint pattern 220 remaining in the second area A2 may be removed.

Referring to FIG. 1N, the second resist pattern 400a, the imprint pattern 220 remaining in the fourth area A4, and the residual-overflowed portion 220a may be removed. Accordingly, the mask pattern 120a in the first area A1 may be exposed.

Referring to FIG. 1O, the first layer 110 may be partially removed using the first and second mask patterns 120a as a mask. Accordingly, a first layer pattern 110a may be formed. For example, the first layer 110 may be dry etched using the first and second mask patterns 120a as an etch barrier.

Referring to FIG. 1P, the first and second mask patterns 120a may be removed. Accordingly, a master template for an imprint lithography method which includes the first layer pattern 110a and the base substrate 100 may be formed. The master template may perform a large area imprint process that is larger than the imprint mold M. For example, the master template may be used to form an in-cell wire grid polarizer for display panel.

Although the imprint mold M usually has a size smaller than a traditional wafer having a diagonal length of 300 mm, the master template may have a size several times larger than the imprint mold M, so that the large area imprint process may be performed. Thus, the combined diagonal length of the first area A1 and the second area A2 in the base substrate 100 of the master template may be greater than 300 mm.

Error of pattern at the boundary between the first area and the second area may be less than 50% of pitch due to the self-alignment. Thus, a seam between the first area and the second area may not be visible to users when the wire grid polarizer manufactured using the master template is applied to a display apparatus. In-cell wire grid polarizers of a display apparatus may be formed using the method.

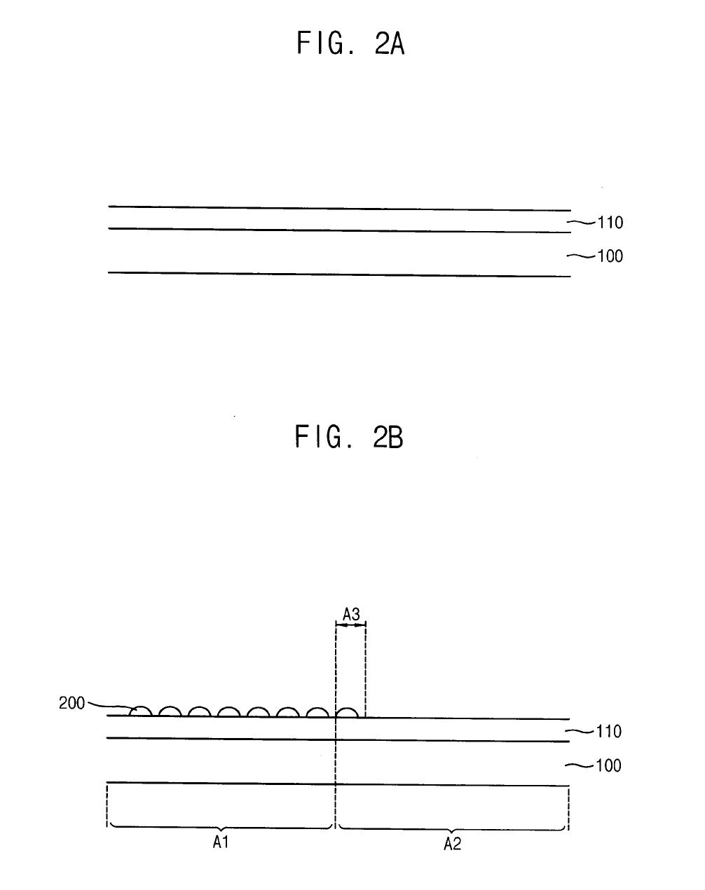

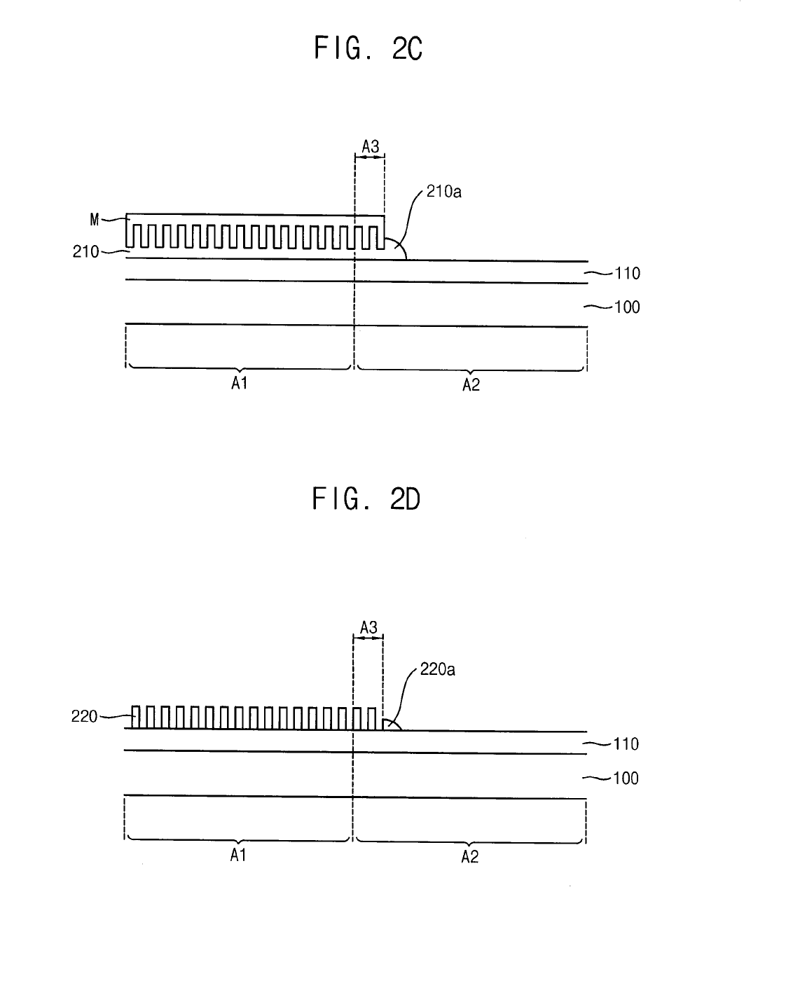

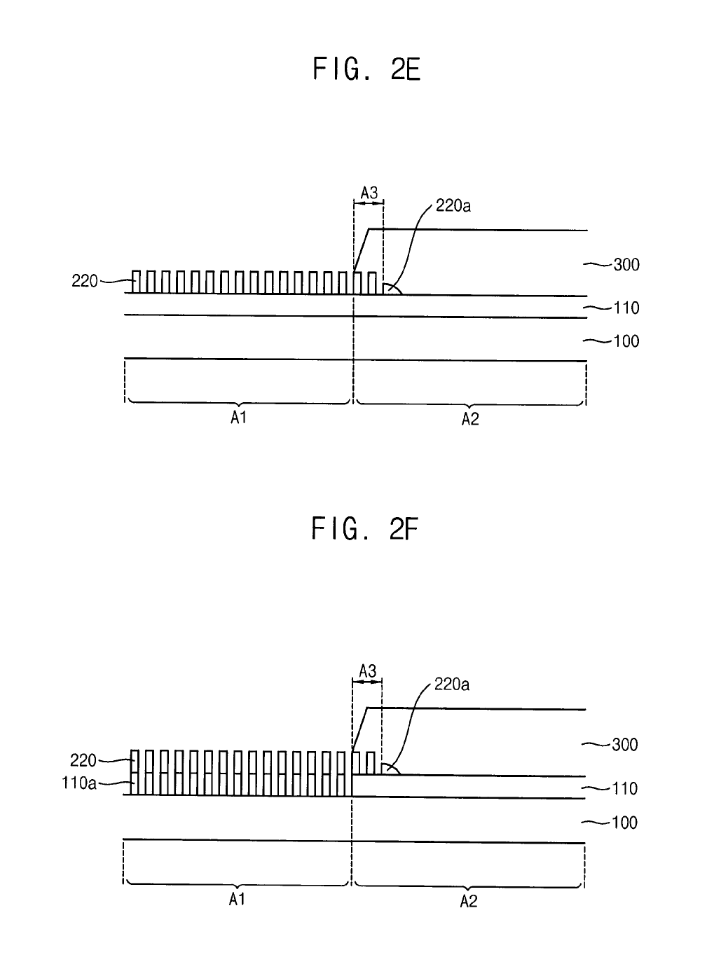

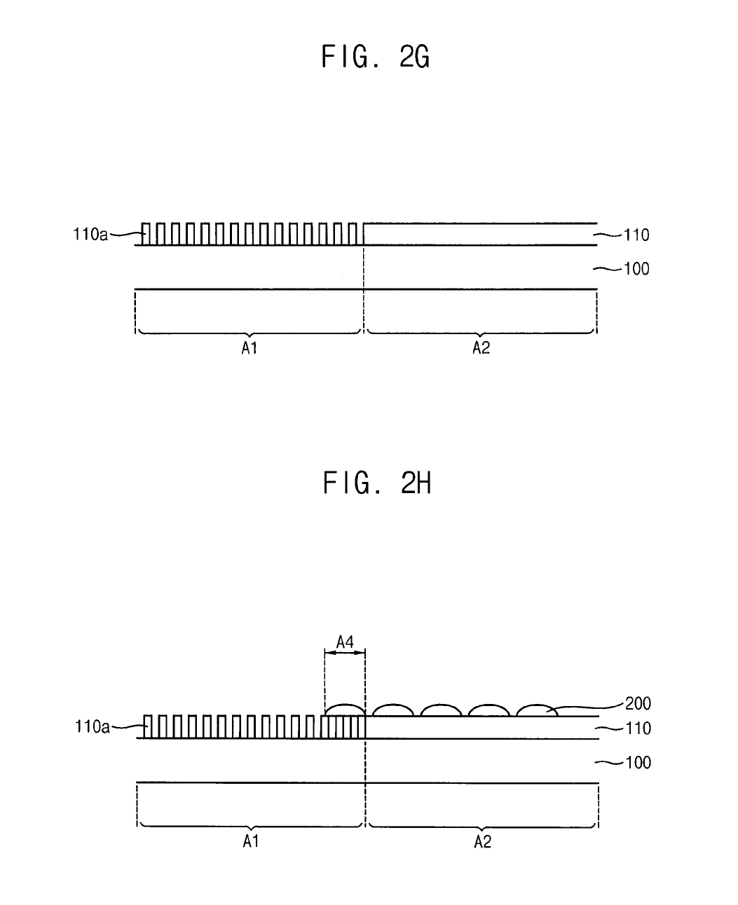

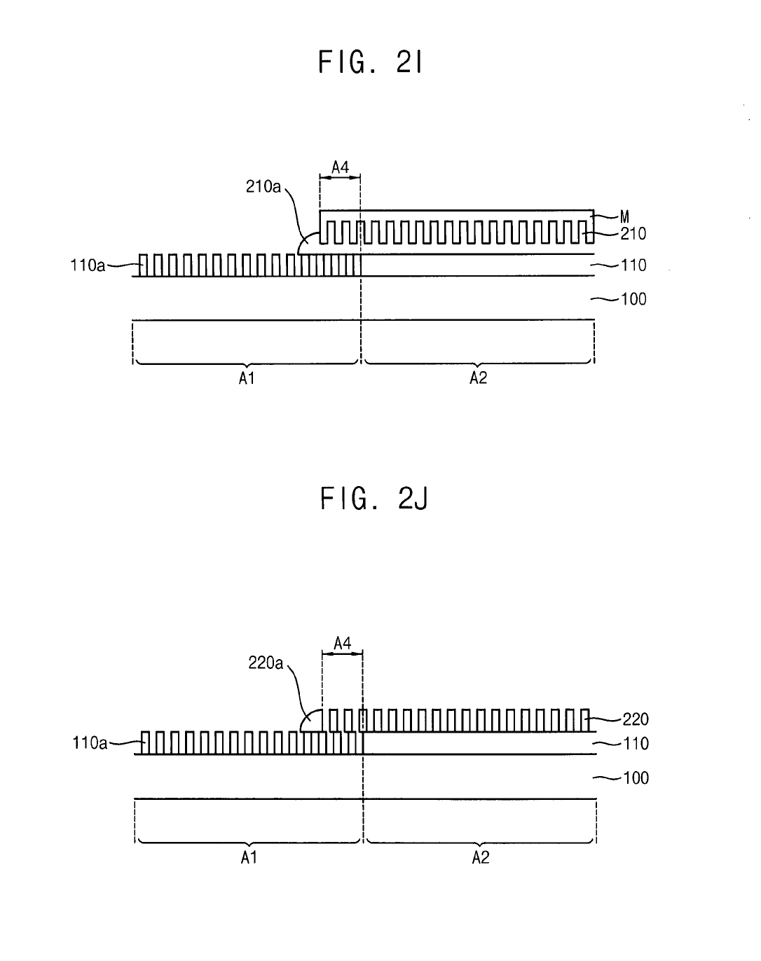

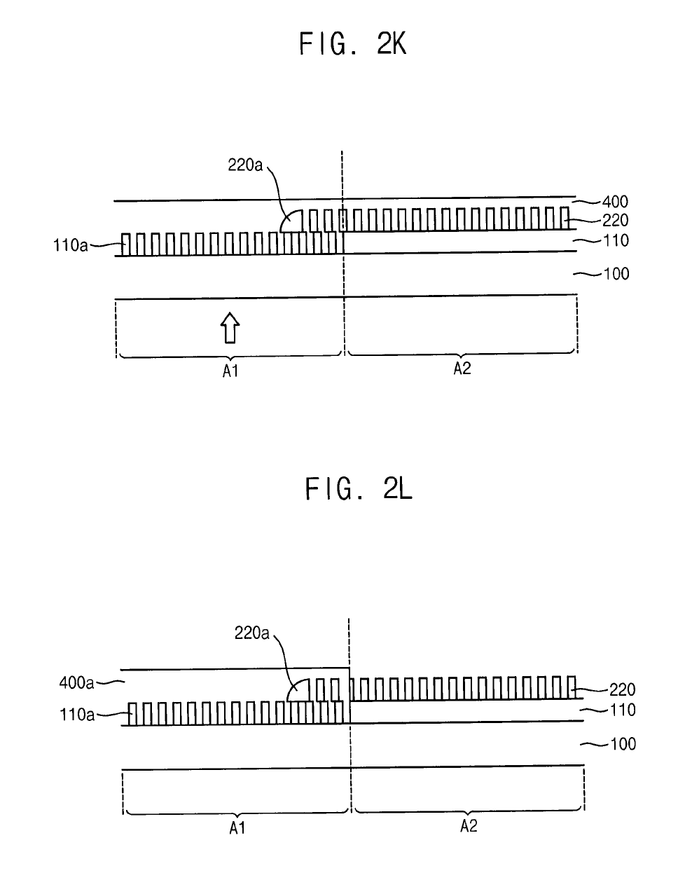

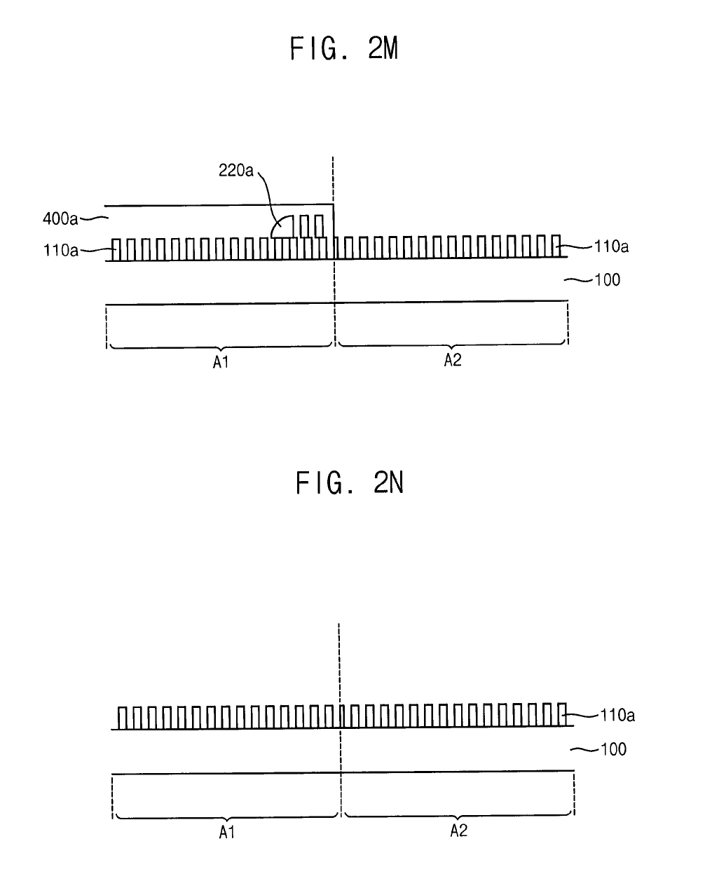

FIGS. 2A to 2N are cross-sectional views illustrating an imprint lithography method according to an exemplary embodiment.

Referring to FIG. 2A, a first layer 110 may be formed on a base substrate 100. The base substrate 100 may include a material having relatively high transmittance, thermal resistance, and chemical resistance. For example, the base substrate 100 may include any one of glass, polyethylenenaphthalate, polyethylene terephthalate, polyacryl, and a mixture thereof. The base substrate 100 may include a material that passes ultraviolet rays, such as quartz, glass, polyethylene terephthalate (PET), and/or polycarbonate (PC). The base substrate 100 may include a material which passes ultraviolet rays such that back exposure process using ultraviolet rays (described later with references to FIG. 2K) may be performed.

The first layer 110 may include a metal, such as aluminum, to form a wire grid pattern. The first layer 110 may be formed using, for example, a printing process, a sputtering process, a CVD process, a pulsed laser deposition (PLD) process, a vacuum evaporation process, an atomic layer deposition (ALD) process, etc.

Referring to FIG. 2B, a resin solution 200 may be provided on the first layer 110 in a first area A1 and a third area A3. The resin solution 200 may be provided as plurality of droplets on the first layer 110. For example, the resin solution 200 may be dropped on the first layer 110 by an inkjet method.

The first area A1 corresponds to a portion of the first base substrate 100 where a first imprint process will be performed. The first area A1 is adjacent to a second area A2 where a second imprint process will be performed. The third area A3 is a portion of the second area A2 which is adjacent to the first area A1. Thus, the resin solution 200 may be provided for an area that is greater than the first area A1, so that the resin solution 200 may cover the first layer 110 in the first area A1 and the third area A3.

The resin solution 200 may be an ultraviolet ray curable resin composition having a low viscosity.

Referring to FIG. 2C, as an imprint mold M is moved towards base substrate 100, the resin solution 200 may be formed into a preliminary pattern 210 using the imprint mold M. Accordingly, a first imprint process may be performed. The resin solution 200 has low viscosity, so that the preliminary pattern 210 between the imprint mold M and the base substrate may be formed by capillary action.

The imprint mold M may have a mold pattern which corresponds to the first area A1 and the third area A3. The imprint mold M may include transparent material which passes the ultraviolet rays. The mold pattern may have an inverted shape of the preliminary pattern 210. For example, the mold pattern may include a protrusion pattern, each protrusion having the same shape and formed a uniform distance from the next protrusion, to form the preliminary pattern 210. The preliminary pattern 210 may correspond to a wire grid pattern. The protrusion pattern may have a pitch of about 50 nm (nanometers) to 150 nm. The pitch may be defined as a sum of the width of one of the protrusion patterns and a distance between protrusions disposed next to each other.

The resin solution 200 may be disposed in the first area A1 and the third area A3, so that the preliminary pattern 210 may be formed in the first area A1 and the third area A3. During the first imprint process, a portion of the resin solution 200 may overflow outside of the third area A3 into the second area A2, so that an overflowed portion 210a may be formed.

The preliminary pattern 210 may include a residual layer formed on the first layer 110, and a plurality of protrusions on the residual layer. Each of the protrusions of the preliminary pattern 210 may be formed between the protrusion patterns of the mold pattern of the imprint mold M.

The ultraviolet rays may be radiated onto the preliminary pattern 210, so that resin solution of the preliminary pattern 210 may be hardened. The imprint mold M may pass ultraviolet rays, so that ultraviolet rays may reach the preliminary pattern 210 through the imprint mold M. Thus, the resin solution of the preliminary pattern 210 may be hardened.

Referring to FIG. 2D, an imprint pattern 220 may be formed by removing the residual layer of the preliminary pattern 210. The imprint pattern 220 may be formed in the first area A1 and the third area A3. The imprint pattern 220 may be formed by etching the preliminary pattern 210 to remove the residual layer between the protrusions. Here, the overflowed portion 210a may be partially removed, so that a residual-overflowed portion 220a may be formed in the second area A2.

Referring to FIG. 2E, a first resist pattern 300 may be formed in the second area A2 on the first layer 110 on which the imprint pattern 220 is formed. The first resist pattern 300 may cover the imprint pattern 220 in the third area A3 and the residual-overflowed portion 220a.

Here, the first resist pattern 300 may be formed with a relatively low level of accuracy, and an area where the first resist pattern 300 is not formed may correspond to the first area A1. Thus, there is no need to perform a precise alignment for the first imprint process and a second imprint process which will be mentioned later.

A photoresist layer may be formed on the first layer 110 on which the imprint pattern 220 is formed. The first resist pattern 300 may be formed by exposure and development of the photoresist layer using an additional mask configured to allow a portion of the photoresist layer which corresponds to the second area A2 to remain.

Referring to FIG. 2F, the first layer 110 may be partially removed using the imprint pattern 220 as a mask. Accordingly, a first layer pattern 110a may be formed in the first area A1. For example, the first layer 110 may be dry etched using the imprint pattern 220 as an etch barrier. Here, the first resist pattern 300 covers the second area A2, so that a portion of the first layer 110 that corresponds to the second area A2 may remain, and the first layer 110 in the first area A1 may be patterned into the first layer pattern 110a.

The imprint pattern 220 remaining in the first area A1 may then be removed.

Referring to FIG. 2G, the first resist pattern 300, the imprint pattern 220 remaining the third area A3, and the residual-overflowed portion 220a may be removed. Accordingly, the first layer 110 in the second area A2 may be exposed.

Referring to FIG. 2H, a resin solution 200 may be disposed on the first layer 110 in the second area A2 and a fourth area A4. The resin solution 200 may be disposed as a plurality of droplets on the first layer 110. For example, the resin solution 200 may be dropped on the first layer 110 by an inkjet method.

The second area A2 corresponds to a portion of the first base substrate 100 where a second imprint process will be performed. The second area A2 is adjacent to a first area A1 where the first imprint process has been performed. The fourth area A4 is a portion of the first area A1 which is adjacent to the second area A2. The resin solution 200 may be disposed on a portion of the first layer pattern 110a in the fourth area A4. Thus, the resin solution 200 may be disposed in an area larger than the second area A2, so that the resin solution 200 may cover the first layer 110 and the portion of the first layer pattern 110a in the second area A2 and the fourth area A4.

The resin solution 200 may be an ultraviolet ray curable resin composition having a low viscosity.

Referring to FIG. 2I, as the imprint mold M moves towards the base substrate, the resin solution 200 may form a preliminary pattern 210 using the imprint mold M. Accordingly, the second imprint process may be performed. The resin solution 200 has low viscosity, so that the preliminary pattern 210 between the imprint mold M and the base substrate may be formed by capillary action.

The imprint mold M may have a mold pattern corresponding to the second area A2 and the fourth area A4. The imprint mold M may be substantially the same as the imprint mold M which is used in the first imprint process. Thus, an imprint lithography process may be performed for an area that is larger than a size of the imprint mold M.

The imprint mold M may have a size smaller than a traditional having a diagonal length of about 300 mm. However, the sum of the first area A1 and the second area A2 may be greater than a size of the traditional wafer.

The resin solution 200 may be disposed in the second area A2 and the fourth area A4, so that the preliminary pattern 210 may be formed in the second area A2 and the fourth area A4. During the second imprint process, a portion of the resin solution 200 may overflow outside of the fourth area A4 into the first area A1, such that an overflowed portion 210a may be formed.

The preliminary pattern 210 may include a residual layer formed on the first layer 110, and a plurality of protrusions on the residual layer. Each of the protrusions of the preliminary pattern 210 may be disposed between adjacent protrusions in protrusion patterns of the mold pattern of the imprint mold M.

Ultraviolet rays may be radiated onto the preliminary pattern 210, so that resin solution of the preliminary pattern 210 may be hardened. The imprint mold M may pass the ultraviolet rays, so that the ultraviolet rays may reach to the preliminary pattern 210 through the imprint mold M. Thus, the resin solution of the preliminary pattern 210 may be hardened.

Referring to FIG. 2J, an imprint pattern 220 may be formed by removing the residual layer of the preliminary pattern 210. The imprint pattern 220 may be formed in the second area A2 and the fourth area A4. The imprint pattern 220 may be formed by etching the preliminary pattern 210 to remove the residual layer between the protrusions. Thus, the overflowed portion 210a may be partially removed, so that a residual-overflowed portion 220a may be formed in the first area A1.

Referring to FIG. 2K, a photoresist layer 400 may be formed on the first layer pattern 110a and the first layer 110 on which the imprint pattern 220 is formed. The photoresist layer 400 may include a negative type photoresist material which is cured by light irradiation. The photoresist layer 400 may cover the imprint pattern 220 in the second area A2, the residual-overflowed portion 220a in the first area A1 and the first layer pattern 110a in the first area A1.

Ultraviolet rays may be radiated onto a bottom surface of the base substrate 100. Thus, the ultraviolet rays may harden the photoresist layer by passing through the base substrate 100, the first layer 110, and the first layer pattern 110a in the first area A1.

The base substrate 100 is transparent, such that the ultraviolet rays may pass therethrough. The first layer pattern 110a in the first area A1 may correspond to a wire grid pattern, such that the ultraviolet rays may pass therethrough. On the other hand, the first layer 110 in the second area A2 may remain without being patterned. Thus, the ultraviolet rays cannot pass the second area A2, such that the photoresist layer 400 in the second area A2 may be not exposed and only the photoresist layer 400 in the first area A1 may be exposed. Thus, during a back exposure process, only a portion of the photoresist layer 400 which corresponds to the first area A1 may be exposed and hardened by self-alignment at the boundary of the first layer pattern 110a in the first area A1 and the first layer 110 in the second area A2.

Referring to FIG. 2L, the second resist pattern 400a in the first area A1 may be formed by development of the photoresist layer 400. The second resist pattern 400a may cover the imprint pattern 220 in the first area A1 and the residual-overflowed portion 220a.

Referring to FIG. 2M, the first layer 110 may be partially removed using the imprint pattern 220 as a mask. Accordingly, a first layer pattern 110a may be formed in the second area A2. For example, the first layer 110 may be dry etched using the imprint pattern 220 as an etch barrier. Here, the second resist pattern 400a covers the first area A1, such that the first layer pattern 110a in the first area A1 may remain, and the first layer 110 in the second area A2 may be patterned into the first layer pattern 110a. Then, the imprint pattern 220 which is remained in the second area A2 may be removed.

Referring to FIG. 2N, the second resist pattern 400a, the imprint pattern 220 remained the fourth area A4 and the residual-overflowed portion 220a may be removed. Accordingly, the first later pattern 110a in the first area A1 may be exposed.

Accordingly, a large area pattern may be formed on the base substrate 100.

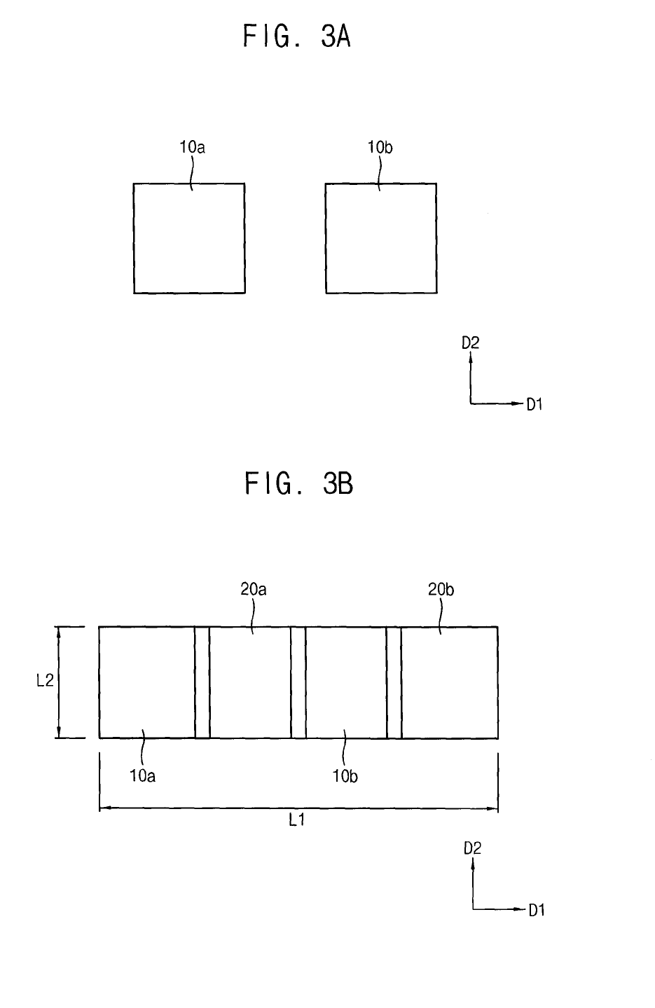

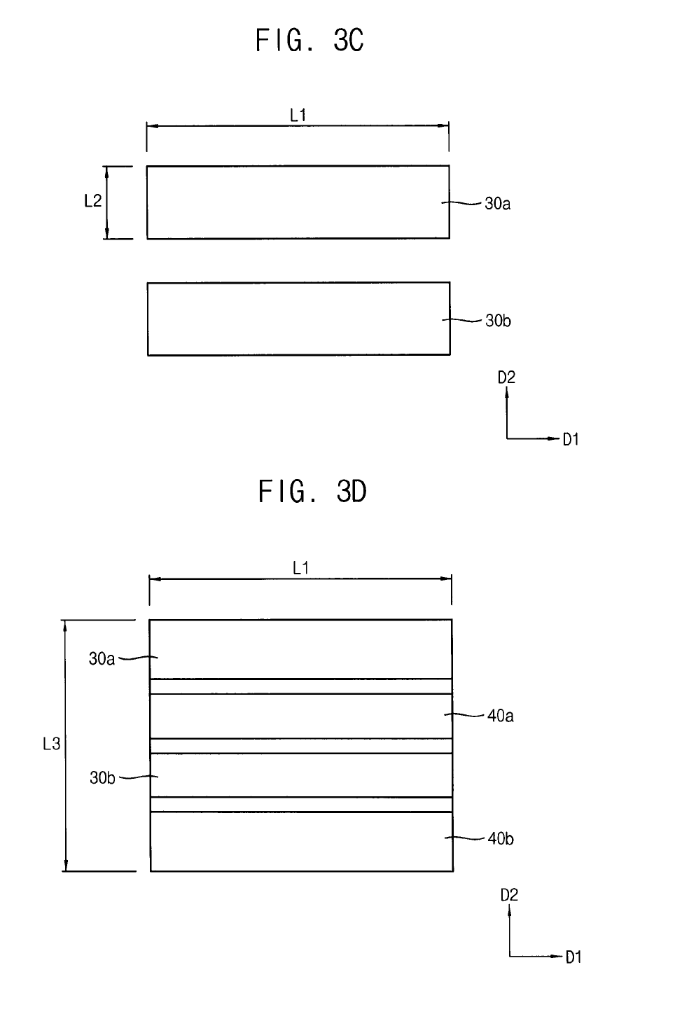

FIGS. 3A to 3D are cross-sectional views illustrating an imprint lithography method according to an exemplary embodiment. A quadrangle in FIGS. 3A to 3D represents a pattern imprinting area using an imprint mold. The imprint lithography method may be the imprint lithograph method explained above.

Referring to FIG. 3A, a substrate may include a surface that extends in a first direction D1 and a second direction substantially perpendicular to the first direction D1. Using an imprint mold, a pattern may be imprinted to a first portion 10a and a second portion 10b which is spaced apart from the first portion 10a in the first direction D1. Processes for the first portion 10a and the second portion 10b may be performed simultaneously or sequentially. Then, the substrate may be etched using the imprinted pattern.

Referring to FIG. 3B, using the imprint mold, a pattern may be imprinted to a third portion 20a and a fourth portion 20b on the substrate. The third portion 20a may be disposed between the first portion 10a and the second portion 10b. The fourth portion 20b may be disposed adjacent to the second portion 10b in the first direction D1. Both ends of the third portion 20a in the first direction D1 may overlap the first portion 10a and the second portion 20b, respectively. An end of the fourth portion 20b may overlap the second portion 10b. Processes for the third portion 20a and the fourth portion 20b may be performed simultaneously or sequentially. Then, the substrate may be etched using the imprinted pattern. Accordingly, a master template having a long side in the first direction D1 may be formed. The master template may have a first length L1 in the first direction D1, and a second length L2 in the second direction D2.

Referring to FIG. 3C, using the master template, a similar process as that shown in FIGS. 3A and 3B may be performed in the second direction D2.

A substrate may include a surface that extends in the first direction D1 and the second direction D2. Using the master template, a pattern may be imprinted to a first portion 30a and a second portion 30b, which is spaced apart from the first portion 30a in the second direction D2. Processes for the first portion 30a and the second portion 30b may be performed simultaneously or sequentially. Then, the substrate may be etched using the imprinted pattern.

Referring to FIG. 3D, using the master template, a pattern may be imprinted to a third portion 40a and a fourth portion 40b on the substrate. The third portion 40a may be disposed between the first portion 30a and the second portion 30b. The fourth portion 40b may be disposed adjacent to the second portion 30b in the second direction D2. Both ends of the third portion 40a in the second direction D2 may overlap with the first portion 30a and the second portion 30b, respectively. An end of the fourth portion 40b may overlap the second portion 30b. Processes for the third portion 40a and the fourth portion 40b may be performed simultaneously or sequentially. Then, the substrate may be etched using the imprinted pattern. Accordingly, a large area master template having extended sides in the first direction D1 and the second direction D2 may be formed. The large area master template may have a first length L1 in the first direction D1, and a third length L3 in the second direction D2.

According to an exemplary embodiment, an imprint lithography method includes providing a base substrate having a first area and a second area, imprinting a pattern in the first area, and imprinting a pattern in the second area. Thus, pattern error at the boundary of the first area and the second area may be reduced due to a self-alignment by a back exposure process.

In addition, a large area imprint lithography process may be performed using a master template formed by the method.

Although certain exemplary embodiments and implementations have been described herein, other embodiments and modifications will be apparent from this description. Accordingly, the inventive concept is not limited to such embodiments, but rather to the broader scope of the presented claims and various obvious modifications and equivalent arrangements.

What is claimed is:

1. An imprint lithography method, comprising:
providing a substrate, the substrate comprising:
a first area;
a second area adjacent to the first area;
a third area comprising a portion of the second area including a boundary of the first area and the second area; and
a fourth area comprising a portion of the first area including the boundary of the first area and the second area;
forming a first imprint pattern on the substrate in the first and third areas;
forming a first resist pattern configured to cover the second area on the substrate on which the first imprint pattern is formed;
etching an object disposed under the first imprint pattern using the first imprint pattern and the first resist pattern as an etch barrier;
removing the first resist pattern;
forming a second imprint pattern on the substrate in the second and fourth areas;
forming a second resist pattern configured to cover the first area on the substrate on which the second imprint pattern is formed;
etching the object disposed under the second imprint pattern using the second imprint pattern and the second resist pattern as an etch barrier; and
removing the second resist pattern.

2. The method of claim 1, wherein forming the first imprint pattern comprises:
disposing a first resin solution in the first area and the third area of the substrate; and
contacting an imprint mold to the first resin solution and hardening the first resin solution to form the first imprint pattern.

3. The method of claim 2, wherein forming the first imprint pattern further comprises:
contacting the imprint mold to the first resin solution and hardening the first resin solution to form a preliminary pattern, the preliminary pattern comprising:
a residual layer disposed on the substrate; and
a plurality of protrusions on the residual layer; and
removing a portion of the residual layer between the protrusions to form the first imprint pattern.

4. The method of claim 2, wherein forming the second imprint pattern comprises:
disposing a second resin solution in the second area and the fourth area of the substrate; and
contacting the imprint mold to the second resin solution and hardening the second resin solution to form the second imprint pattern.

5. The method of claim 4, wherein the imprint mold comprises protrusions spaced apart from each other by a set distance, all of the protrusions and having identical shapes.

6. The method of claim 5, wherein the protrusions have a pitch between 50 nm to 150 nm.

7. The method of claim 1, wherein before forming the first imprint pattern, the method further comprises:
forming a first layer on the substrate, the first layer comprising a transparent material configured to pass ultraviolet rays therethrough; and
forming a mask layer on the first layer.

8. The method of claim 7, wherein etching the target layer disposed under the second imprint pattern comprises etching a portion of the mask layer to form a first mask pattern.

9. The method of claim 8, wherein forming the second resist pattern comprises:
forming a photoresist layer on the substrate on which the second imprint pattern is formed;
radiating ultraviolet rays onto the photoresist layer through the substrate, the first layer, and the first mask pattern to harden the photoresist layer in the first area; and
developing the photoresist layer to form the second resist pattern.

10. The method of claim 9, wherein etching the target layer under the second imprint pattern comprises forming a second mask pattern by etching a portion of the mask layer.

11. The method of claim 10, wherein the first mask pattern and the second mask pattern are formed in the first area and the second area, respectively, so that the first mask pattern and the second mask pattern are formed continuously on the substrate, and the method further comprises etching the first layer using an etch barrier comprising the first and second mask patterns.

12. The method of claim 10, wherein the first layer comprises silicon compound.

13. The method of claim 1, wherein before forming the first imprint pattern, the method further comprises forming a metal layer on the substrate.

14. The method of claim 1, wherein:
etching the object disposed under the first imprint pattern comprises forming a first metal layer pattern by etching a portion of the metal layer; and
etching the object disposed under the second imprint pattern comprises forming a second metal layer pattern by etching a portion of the metal layer.

15. The method of claim 14, wherein:
the first and second metal layer pattern forms a wire grid pattern;
a sum of width of a wire grid of the wire grid pattern and a distance between adjacent wire grids of the wire grid pattern defines a pitch; and
an error of the pitch at the nearest wire gird to a boundary of the first metal layer pattern and the second metal layer pattern is less than 50% of the pitch.

16. A method of manufacturing a mater template for imprint lithography, comprising:
sequentially forming a first layer and mask layer on a substrate;
forming a first imprint pattern on a first portion of the mask layer;
etching the first area of the mask layer using the first imprint pattern as an etch barrier to form a first mask pattern;
forming a second imprint pattern on a second portion of the mask layer disposed adjacent to the first mask pattern;
forming a photoresist layer on the substrate on which the second imprint pattern is formed;
forming a resist pattern on the first mask pattern by back exposure and development of the photoresist layer;
etching the second portion of the mask layer using the second imprint pattern and the resist pattern as an etch barrier to form a second mask pattern; and
etching the first layer using the first and second mask pattern as an etch barrier.

17. The method of claim 16, wherein:
forming the first imprint pattern comprises forming a 1-a imprint pattern and a 1-b imprint pattern, the 1-b imprint pattern spaced apart from the 1-a imprint pattern on the mask layer; and
forming the first mask pattern comprises forming a 1-a mask pattern and a 1-b mask pattern spaced apart from the 1-a mask pattern by etching the mask layer using the 1-a and 1-b imprint patterns, respectively, as etch barriers.

18. A master template for imprint lithography, comprising:
a substrate comprising a first area and a second area contacting the first area; and
a master pattern disposed in the first area and the second area on the substrate, wherein:
the master pattern comprises protrusions in the first and second area, the protrusions being spaced apart from each other by a set distance and all having identical shapes;
a sum of a width of a protrusion of the protrusions and distance between adjacent protrusions defines an overall pitch; and
a pitch of the protrusion at the nearest to a boundary of the first area and the second area in a range of ½ to 3/2 of the overall pitch.

19. The master template of claim 18, wherein the overall pitch of the protrusions in the first area and the second area is between 50 nm to 150 nm.

20. The master template of claim 19, wherein a combined diagonal length of the first area and the second area is greater than 300 mm.
